(19) United States
(12) Patent Application Publication
(10) Pub. No.: US 2011/0197943 A1
(43) Pub. Date: Aug. 18, 2011

(54) Flow arrangement for a solar system

(76) Inventors: Harry Pleva, Horb (DE); Ralf Pleva, Horb (DE)

(21) Appl. No.: 12/656,789

(22) Filed: Feb. 17, 2010

(51) Int. Cl. H01L 31/042

(52) U.S. Cl. 136/244

(57) ABSTRACT

The invention relates to a flow arrangement (3) for a solar system as well as a solar system having such a flow arrangement (3). The solar system includes an arrangement of photovoltaic solar modules (1) which are aligned inclined to the horizontal and which face toward the sun with an irradiation side (2). The flow arrangement (3) is for generating a water film (4), which forms on the irradiation side (2) of the solar modules (1) and flows exposed to the ambient. The flow arrangement (3) also includes a water outlet (6) extending in a horizontal transverse direction (5). The flow arrangement (3) further includes at least two quieting chambers (7, 8). The last quieting chamber (8) in the throughflow direction is provided with a water outlet (6). A partition wall (9) runs between the quieting chambers (7, 8) and has a flow-over edge (10) which extends in the horizontal transverse direction (5).

### FIELD OF THE INVENTION

The invention relates to a flow arrangement for a solar system as well as a solar system incorporating the flow arrangement.

### BACKGROUND OF THE INVENTION

Solar systems having photovoltaic solar modules generate electrical energy when subjected to incoming radiation from the sun and this energy is supplied directly to a consumer or is fed into the public power grid. Although sun energy is available free of cost, the low degree of efficiency of present day photovoltaic solar modules, however, requires a high cost of investment and a high maintenance cost which limit the economic operation of photovoltaic solar systems. Especially in higher degrees of latitude whereat, because of geographic and meteorological conditions, only a limited duration of sunshine is available, comparatively large, cost-intensive solar systems are needed for obtaining a desired mean quantity of electrical energy.

Numerous measures are known for increasing the degree of efficiency and for reducing cost. Solar modules of limited size can, for example, be pivoted in horizontal and vertical directions and can track the position of the sun. In this way, an incidence of sun radiation is ensured at at least approximately right angles to the irradiation side of the solar module. The mean duration of incidence of the rays of the sun is thereby, however, not extendible.

The loss of efficiency with increasing modular temperature is known as a further limiting factor for the yield of electric current. In numerous arrangements known from the state of the art, an active cooling of the solar modules is suggested via a water circulation loop. International patent publication WO 2008/025461 and German utility model 295 07 178 U1 disclose, for this purpose, flow arrangements for a solar system. The particular flow arrangement is provided for generating a water film which flows exposed to the ambient and which forms on the side exposed to radiation of the solar module. This water film flows over the solar modules and cools the solar modules and thereby increases their efficiency. Furthermore, the water film carries away dirt particles whereby the surface always remains clean for increasing the efficiency. The solar modules are also protected against abrasive environmental influences.

In practice, it has, however, been shown that the generation of a uniform water film, which is suitable with respect to its thickness, is difficult. For solar modules, which are adjustable with respect to their inclination, the water film has to adapt to the inclination which is selected differently in each case. Overall, the water film should neither be too thick nor too thin and must furthermore exhibit a uniform thickness over the entire surface of the solar modules. The two above-mentioned publications disclose no suitable means as to how the generation of such a uniform water film can be obtained.

### SUMMARY OF THE INVENTION

It is an object of the invention to improve a generic flow arrangement in such a manner that an areal uniformly distributed water film is formed on the solar module.

The flow arrangement of the invention is for a solar system having an array of photovoltaic solar modules aligned inclined to the horizontal. Each one of the solar modules has an irradiation side facing toward the sun and the flow arrangement is provided to generate a water film flowing exposed to the ambient and forming on the irradiation side of each of the solar modules. The flow arrangement includes: a water source for supplying a flow of water; a first quieting chamber connected to the water source for receiving the flow of water therefrom; a second quieting chamber disposed downstream of the first quieting chamber in a throughflow direction; a partition wall running between the first and second quieting chambers and defining a flow-over edge extending in a horizontal transverse direction over which water flows from the first quieting chamber to the second quieting chamber in the throughflow direction; and, the second quieting chamber having a water outlet extending in the horizontal transverse direction from which water flows to form the water film.

It is a further object of the invention to provide a solar system having a flow arrangement which reliably exhibits a high efficiency under different weather conditions.

The solar system of the invention includes: an array of photovoltaic solar modules aligned inclined to the horizontal; each one of the solar modules having an irradiation side facing toward the sun; a flow arrangement for generating a water film flowing exposed to the ambient and forming on the irradiation side of each of the solar modules; and, the flow arrangement including: a water source for supplying a flow of water; a first quieting chamber connected to the water source for receiving the flow of water therefrom; a second quieting chamber disposed downstream of the first quieting chamber in a throughflow direction; a partition wall running between the first and second quieting chambers and defining a flow-over edge extending in a horizontal transverse direction over which water flows from the first quieting chamber to the second quieting chamber in the throughflow direction; and, the second quieting chamber having a water outlet extending in the horizontal transverse direction from which water flows to form the water film.

A flow arrangement for a solar system as well as a solar system having a corresponding flow arrangement are disclosed. The flow arrangement has at least two quieting chambers. The last quieting chamber in the throughflow direction is provided with a water outlet extending in a horizontal transverse direction and a partition wall runs between the quieting chambers and has a flow-over edge extending in the horizontal transverse direction.

Water is first introduced via a water feed into the first quieting chamber which extends in the transverse direction. This first quieting chamber has no direct flow-conducting connection to the water outlet of the flow arrangement. The entering water is therefore compelled to spread in the transverse direction of the first quieting chamber thereby causing a quieting of the flow. The water, which is quieted in this manner and is distributed at least approximately uniformly, thereafter flows over the flow-over edge of the partition wall whereby a further flow quieting occurs. In this state, the water is already distributed uniformly in the transverse direction and passes in this uniformly distributed form into the second quieting chamber where a flow-quieted water supply for the water discharge is collected with this water supply being distributed uniformly in the transverse direction. The water discharge is fed from this quieted water supply. Thereafter, a uniformly distributed, film-like water flow passes out of the water discharge along its total transverse extent. The water flow is applied as a water film to the outer side of the solar module with a thickness constant in the transverse direction. The formation of regions having increased flow velocity or having below average flow velocity is reliably avoided as is the formation of regions having deviating film thickness. The thickness of the water film can be adapted exactly to the weather conditions present because of its uniformity and can also be adapted to the geometric conditions of the inclination of the solar modules. The cooling action for the solar modules and the electric efficiency resulting in dependence thereon can be precisely and reliably adjusted. The temperature of the water film can be properly adjusted by adjusting the film thickness and flow speed also for the use as a warm water energy source.

It can be practical that the partition wall between the two quieting chambers does not extend downwardly to the base of the chamber housing; instead, a narrow gap is allowed to remain between the lower edge of the partition wall and the base. The flow-over edge of the partition wall is then here configured as a lower edge running in the transverse direction which, together with the base of the quieting chambers, forms a transverse-running gap through which the water passes from the first quieting chamber into the second quieting chamber. In a preferred embodiment, the flow-over edge is an upper overflow edge in the direction of gravitational force. As soon as the inlet-side first quieting chamber has reached an adequate fill level, the water flows from there out over the exactly horizontally aligned overflow edge into the second quieting chamber. The configuration of a nozzle-like slot is not necessary. Rather, an overflow, which is distributed uniformly in the transverse direction, is formed with low flow velocity and high uniformity whereby the quieting action on the water flow is further improved.

It can be practical that the two quieting chambers extend only over a part region of the width of the water discharge. For this purpose, the quieting chambers have a width of at least 60% (preferably at least 80% and especially at least 90%) of the width of the water discharge. Advantageously, the two quieting chambers extend over the total width of the water discharge so that the water discharge reliably generates a uniform water film even in its edge regions. The water discharge itself corresponds with respect to its width at least to the width of an individual solar module so that this solar module likewise is charged with a uniform water film over its entire width. The forming of individual zones on the solar module having inadequate or excessively thick water film is avoided.

In an advantageous embodiment, a quieting lattice is arranged at least in the inlet-side quieting chamber. The quieting lattice operates on the entering water with its disordered flow as a damping element and contributes with a high effectiveness to quiet the water flow and to make the same uniform over the width of the quieting chamber.

The water discharge can be configured, as a flat nozzle, a row of apertures or the like and is advantageously formed by a threshold having a threshold edge extending in the horizontal transverse direction. As soon as an adequate fill level is formed in the second quieting chamber, the water exits in a manner comparable to the above-described overflow edge over the threshold edge toward the outside onto the solar modules. The formation of non-uniformities in the water film is reliably avoided with an exactly horizontal alignment of the threshold edge.

Preferably, a control unit for adjusting the free flow cross section of the water discharge is provided. The control unit is especially formed by a toothed strip adjustable in elevation and overlapping the threshold edge. Depending upon the height adjustment, the teeth cover a portion of the threshold edge while water can exit over the threshold edge through the gaps between the teeth. These gaps can be adjusted in size by a stroke movement of the toothed strip whereby the water flow can be precisely adapted to the present requirement. The teeth themselves contribute to a further quieting of the water flow. For an adequately fine tooth configuration, the teeth themselves define no technically relevant disturbance of the water flow. Instead, the many small component flows passing through the toothed gaps combine after a short running distance downstream of the toothed strip to a uniform water film which is constant with respect to its thickness but can be adjusted in its thickness and flow velocity.

Different thicknesses of the water film can occur in the transverse direction because of the following: lateral inclination errors of the solar modules and of the flow arrangement, which can occur in the transverse direction, as well as non-symmetries in the filling flow of the quieting chambers. In the worst case, the water film does not form at all at some locations while, at other locations, the water film is too thick. An elevation and/or inclination adjustment for the solar modules and/or the flow arrangement can be practical to compensate for such inclination errors and for achieving a water film having a uniform thickness in the transverse direction. Preferably, a water feed is provided which opens especially centrally and transversely to the horizontal transverse direction into the first quieting chamber. Adjustable deflecting means for deflecting the inflowing water flow into the horizontal transverse direction are arranged in the region of the water feed. In the base setting, a symmetrical filling is generated by the especially central inflow of the quieting chamber. This symmetrical filling leads in precise horizontal alignment to a water film having constant thickness in the transverse direction. Insofar as lateral inclination errors are, however, present, a filling profile of the quieting chambers departing from symmetry can be adjusted via the adjustable deflecting means. This filling profile operates counter to the lateral inclination error. In this way and with simple means, a uniform thickness of the water film can be adjusted notwithstanding the inclination errors without a geometric compensation of the inclination error being necessary.

The deflecting means can be adjustable guide plates or the like. In a preferred embodiment, the water feed includes a rotatable feed stub having a rotational axis lying transversely to the transverse direction. The feed stub has a water channel section facing toward the first quieting chamber. The water channel section lies at an angle to the rotational axis departing from 0° to form the deflection means. With a simple adaptive rotation of the feed stub, the angled water channel section can be rotated to the left or to the right starting from a center neutral position whereby the incoming water flow receives the desired lateral directional component. The arrangement is effective and constructively simple in configuration. The adjustment of the water film thickness can be undertaken without special ancillary means. The rotatable feed stub can be fixed in the found rotational angular position in a simple manner.

Surfactants are preferably added to the water as a further measure for forming a uniform water film which is as thin as possible. Even for a very thin adjustment of the water film, the water film tends not to tear open because of the missing surface tension so that the solar module subjected to flow remains uniformly covered by the water film.

In an advantageous embodiment, the surface of the solar modules on the side receiving radiation has longitudinal guides running in inclination direction. In this way, the sensitivity of the water film is reduced against geometric alignment errors, lateral wind influences or the like. A uniform water film is maintained even with solar modules, which are not aligned exactly even or in the slope line, or for disturbing weather influences. This is so because the formation of directional components of the film flow transverse to the slope line is avoided.

In a further preferred embodiment, a control unit is provided for a fill level control of the water in the quieting chamber, especially, in the last quieting chamber. This ensures a uniform water fill level which makes available a constant hydrostatic pressure at the water discharge. The desired and once undertaken adjustment of the water film in thickness and flow velocity remains permanently maintained.

In a preferred embodiment, a transition strip is provided for placement in the transition region of two mutually adjoining solar modules in the inclination direction. The transition strip extends in the transverse direction and has guide devices distributed in the transverse direction and aligned in the inclination direction. The arrangement described above is based on the recognition that the solar modules of commercial size must be arranged one below the other while forming joints in the inclination direction. Without further measures, these joints disturb the formation of the uniform water film. The joint is bridged with the transition strip. The guide devices prevent a transverse flow of the water film in this transition region and permit only a flow over of the joints in the inclination direction. In this way, it is ensured that the oncoming water film which is uniform upwards maintains its uniform thickness and flow distribution also after passing over the joint.

In an advantageous further embodiment, the transition strip is formed by a profile which, in the assembled state, rises above the surface of the solar modules on the side thereof subject to incident radiation and spans over the joint between the solar modules. The guide devices are formed by an alternating arrangement of ribs and intermediate-lying channels. The type of construction of the transition strip raised above the surface generates a slight damming action of the oncoming water film whereby a flow quieting again occurs. The alternating arrangement of ribs and intermediate-lying channels guides the backed up and quieted water to the next solar module exactly in the inclination direction while avoiding transverse flows. For an adequately tight arrangement of ribs and channels, the component flows passing through the individual channels join automatically together after passing the transition strip to a uniform water film which then, anew, flows down, as on the input side, with uniform thickness distribution and flow distribution at the outlet end solar module. The channels are self cleaning as a consequence of their type of construction open in the outer and/or radial direction so that a contamination or blockage because of leaves is avoided.

Various types of construction are suitable for forming the transition strips. In a simple, cost effective and efficient type of construction, the transition strip is formed by a corrugated strip cut in the longitudinal direction. The corrugated strip can be obtained at low cost as meter goods or can be produced by milling and cut, for example, in half in the longitudinal direction. Such a half cross section or part cross section of a corrugated strip can be easily assembled and effectively bridges the intermediate-lying joint while maintaining a uniform water film.

### BRIEF DESCRIPTION OF THE DRAWINGS

The invention will now be described with reference to the drawings wherein:

FIG. 1 is a perspective schematic of a house having a shed roof and a photovoltaic solar system placed thereon with the solar system having a flow arrangement;

FIG. 2 is a perspective view, partially in section, showing an enlarged detail view of the flow arrangement of FIG. 1 interacting with a solar module;

FIG. 3 is a cross-sectional view of the flow arrangement of FIGS. 1 and 2 showing details as to the interior assembly and configuration of the water discharge;

FIG. 4 is a section plan view showing the flow arrangement of FIGS. 2 and 3 in the region of the water feed with details as to the feed stub adjustable in rotation;

FIG. 5 is a cross-sectional view of the feed stub of FIG. 4 showing additional detail as to the possible rotational angular positions;

FIG. 6 is a plan view of an enlarged detail view of the solar system of FIG. 1 in the joint region of two mutually adjoining solar modules in the inclined direction together with a transition strip spanning the intermediate-lying joint; and,

FIG. 7 is a cross-sectional view showing the arrangement of FIG. 6 with details as to the transfer of the water film from one solar module to the next solar module following in the direction of inclination.

### DESCRIPTION OF THE PREFERRED EMBODIMENTS OF THE INVENTION

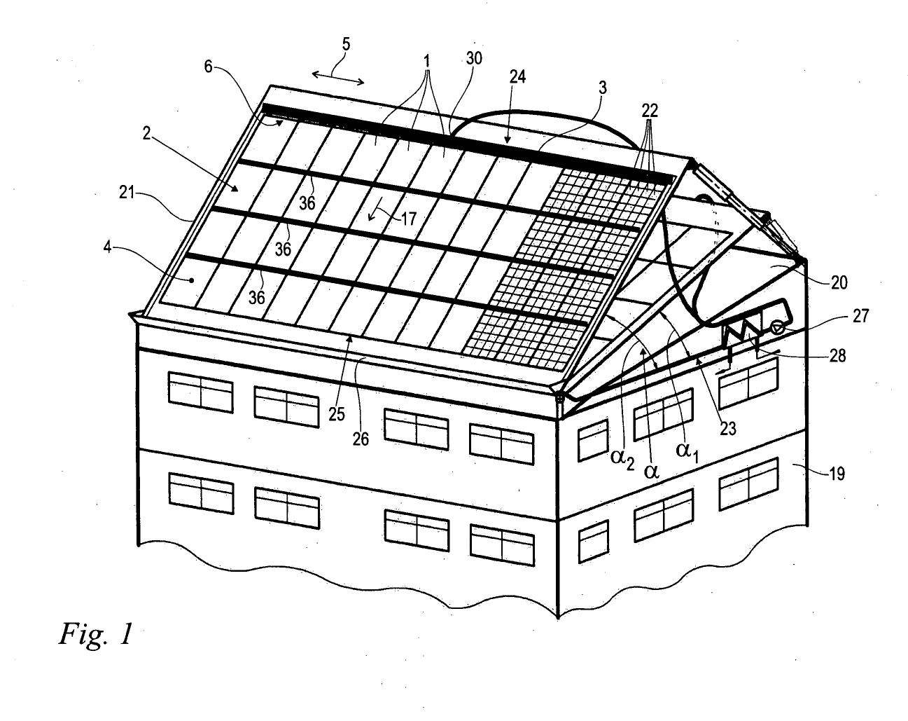

FIG. 1 shows a perspective schematic of a building 19 having a roof 20 configured as a shed roof in the embodiment shown. The roof can also be a gabled roof or the like. The building 19 is disposed in the northern hemisphere. The roof of the shed roof is at least approximately aligned to the south toward the mid day sun. In the same manner, alignment to the north is provided in the southern hemisphere. A carrier construction 21 is arranged on the shed roof 20 in the same alignment to the celestial direction. The carrier construction corresponds at least approximately to the roof surface of the shed roof 20 or the base surface of the building 19.

The carrier construction 21 is part of a solar system and carries a plurality of photovoltaic solar modules 1 arranged in a plane of the carrier construction 21. The solar modules in turn each have a plurality of solar cells 22 connected to each other. The array of solar modules 1 is mounted by means of the carrier construction 21 on the roof 20 of building 19 and is inclined at an angle α to the horizontal in an inclined direction 17. The angle α is adjustable in an angular range between a lower angle α₁ and an upper angle α₂. In this way, the side 2 of the solar module 1 subjected to radiation faces the sun at least over a greater part of its daylight path.

The solar system includes a flow arrangement 3 which is provided to generate a water film 4. The water film 4 flows exposed to the ambient and is formed on the irradiation side 2 of the solar module 1. In the embodiment shown, water is selected to form the water film 4 to which surfactants are added for making the flow of the water uniform. The water film 4 is part of an indicated water circulation loop or water circuit 23. The flow arrangement 3 extends in a horizontal transverse direction indicated by double arrow 5 in the region of an upper edge 24 of the array of solar modules 1. The flow arrangement 3 is provided with water outlets 6 which likewise extend in the horizontal transverse direction 5 over the width of each solar module 1. The water supplemented by surfactants is discharged on the irradiation side 2 of the solar module 1 from the water outlets 6. A water film 4 forms which covers the entire surface of the irradiation side 2 of the solar module 1 and, under the action of gravity, flows in the direction of a lower edge 25 of the solar modules 1, that is, in the inclination direction 17.

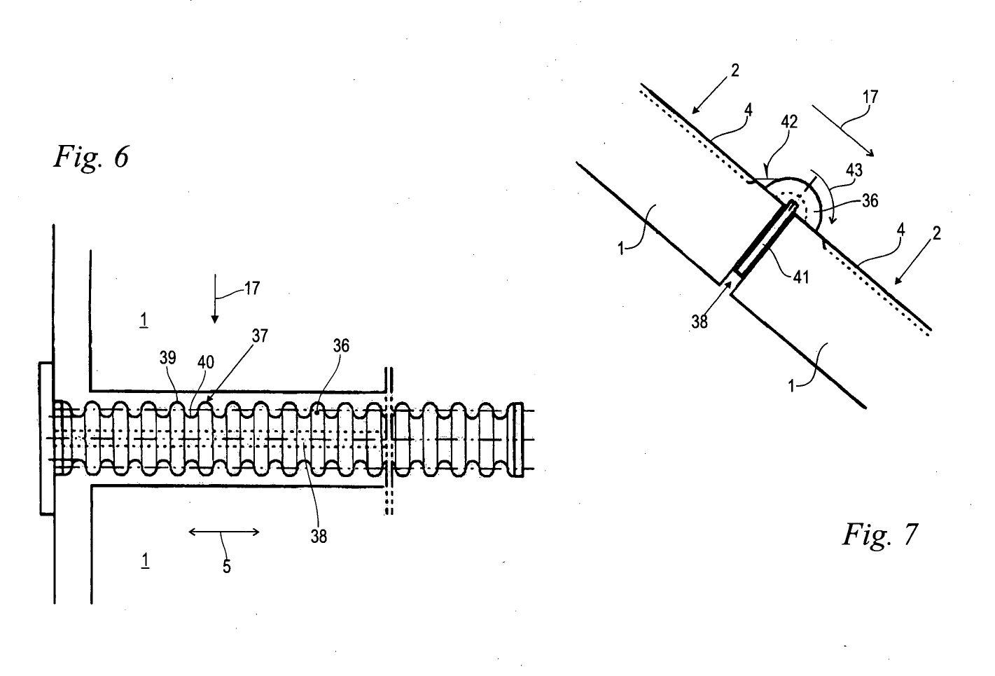

Transition strips 36 are provided which extend in the transverse direction 5. The transition strips cover the transition region of each two mutually adjoining solar modules 1 in the inclination direction 17 so that the water film 4, starting from the flow arrangement 3, can form over the entire surface of the solar module 1. The transition strips 36 span the entire width of the mutually adjoining solar modules 1 in the transverse direction 5. Additional details in connection herewith are described hereinafter in connection with FIGS. 6 and 7.

The water of the water film 4 is collected at the lower edge 25 by a collecting gutter 26 and is, via the closed water circuit 23, conducted back by a pump 27 via a water feed 30 to the flow arrangement 3.

The liquid film 4 is exposed to the ambient, that is, it is not covered. Dirt such as dust or the like entrained from the ambient is transported with the water film 4 to the collecting gutter 26 and can, for example, be filtered out of the closed water circuit 23 by a filter (not shown). At the same time, the water film 4 exercises a protective function for the solar modules 1 with their photovoltaic solar cells 22 against abrasive ambient influences. In the closed water circuit 23, a schematically-indicated heat exchanger 28 is provided which generates a cooling of the water, that is, the water film 4. Furthermore, the water film exposed to the ambient has an evaporation rate which additionally cools the water film 4. The cooled water film 4 cools the solar cells 22 and thereby increases the electrical efficiency thereof. With the heat exchanger 28, a heat accumulator (not shown), for example, in the form of a water tank, a swimming pool or the like can be heated.

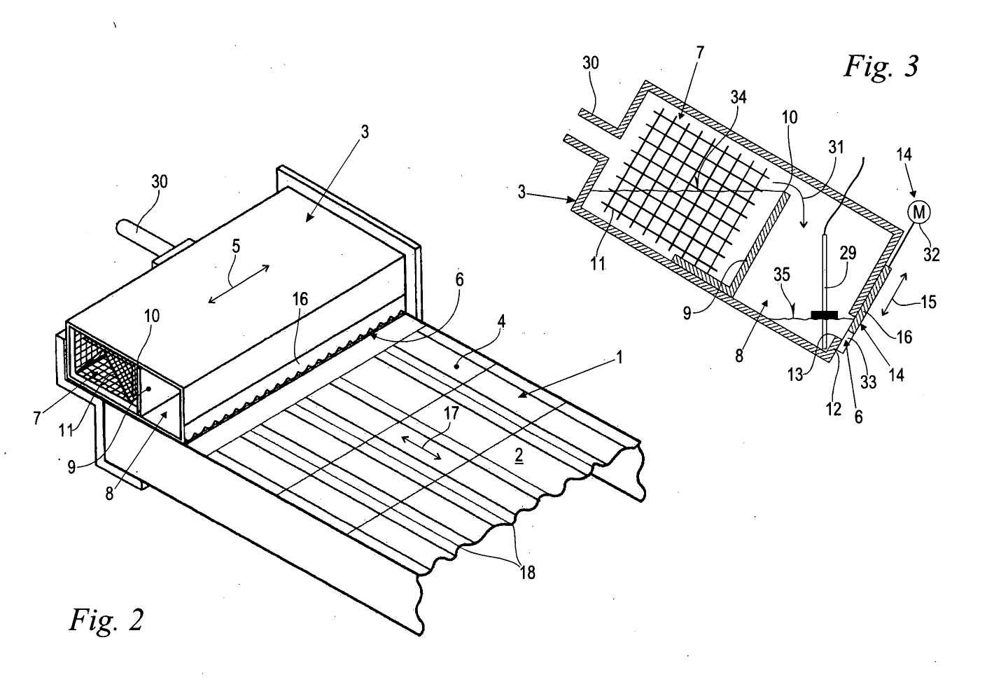

FIG. 2 shows the flow arrangement 3 of FIG. 1 in a perspective view partially in section. FIG. 2 shows the flow arrangement interacting with a solar module 1 which is likewise shown partially in section. The flow arrangement 3 includes a case extending in the transverse direction 5. Two quieting chambers (7, 8) are formed by the walls of the case and a partition wall 9 arranged inside thereof. The water feed 30 opens into the first quieting chamber referred to the throughflow direction. The water feed 30 is fed with water by the pump 27 (FIG. 1). The second and here last quieting chamber 8 in flow direction is provided with the water outlet 6. Additional quieting chambers can be provided.

In the first quieting chamber 7, a quieting lattice 11 is mounted in the form of a multiply bent-over wire lattice. In lieu of the wire lattice, rods, strip-shaped or plate-shaped elements can be provided as quieting measures for the water flow forming in the first quieting chamber 7. Furthermore, it can be practical to mount a quieting lattice 11 or other comparable means in the second quieting chamber 8. A toothed strip 16 is mounted in the region of the water outlet 6. Further details as to the constructive configuration of the flow arrangement 3 will be described hereinafter in connection with FIGS. 3 to 5.

The section of the flow arrangement 3 shown here extends in the horizontal transverse direction 5 in such a manner that the width of the water outlet 6 corresponds at least to the width of an individual solar module 1. The same applies to the two quieting chambers (7, 8) which likewise exhibit the same width as the solar module 1 and as the water outlet 6. The flow arrangement shown in FIG. 1 includes precisely as many of the sections shown here as solar modules 1 lie one adjoining another in the transverse direction. It can, however, also be practical to configure the flow arrangement 3 with one of the sections shown here extending over the width of several or all solar modules 1.

A water film 4 made uniform with respect to thickness and flow distribution exits from the water outlet 6 and is applied over the entire width and therewith over the entire surface of the irradiated side 2 of the solar module 1. The solar module 1 is inclined in the inclination direction to the vertical direction given by the double arrow 17 so that the water film 4 flows off in the inclination direction 17 on the outer side of the solar module 1. On the irradiated side 2, the surface of the solar module has optional longitudinal guides 18 for the water film 4 which run in the inclination direction 17. The longitudinal guides 18 can be longitudinal grooves, longitudinal struts or the like. Direction components of the flow of the water film 4 transverse to the slope line or to the inclination direction 17 are avoided thereby.

FIG. 3 shows a schematic cross section view of the flow arrangement 3 of FIGS. 1 and 2. As shown in FIG. 3, the two quieting chambers (7, 8) are partitioned from each other by a partition wall 9. The cross-sectional longitudinal axis of the flow arrangement 3 is inclined by the same amount as the carrier construction 21 (FIG. 1) with the solar modules 1. The inclination angle of the flow arrangement 3 changes with the change of the inclination angle α (FIG. 1).

The water flowing in through the water feed 30 into the first quieting chamber 7 is, by the quieting lattice 11, uniformly distributed in the transverse direction 5 (FIG. 2) and flow quieted and forms a first water level 34 as a consequence of the backup effect of the partition wall 9. The partition wall 9 is provided with a flow-over edge 10 extending in the horizontal transverse direction 5 (FIG. 2). The flow-over edge is here configured as an upper overflow edge in the direction of the force of gravity. After the first water level 34 has climbed up to the flow-over edge 10, the water flows out of the first quieting chamber 7 in correspondence to arrow 31 over the flow-over edge 10 into the second quieting chamber 8 where a second water level 35 is formed in the region of the water outlet 6. The height of the fill level or of the second water level 35 in the second quieting chamber 8 is measured by a fill-level sensor 29 indicated schematically. The fill-level sensor 29 together with the pump 27 and the closed water circuit 23 (FIG. 1) forms a control loop by means of which the height of the second water level 35 is held constant.

The second quieting chamber 8 is provided with a threshold 12 extending in the horizontal transverse direction 5 (FIG. 2) which, referred to the direction of gravitational force, is limited in the upward direction by means of a threshold edge 13 likewise extending in the horizontal transverse direction 5. The threshold 12 together with its threshold edge 13 defines the water outlet 6.

As shown in FIG. 3, the toothed strip 16 shown here in cross section is adjustable by means of a drive 32 in up direction indicated by a double arrow 15. The teeth 33 of the toothed strip 16 at least partially cover the threshold 12 with its threshold edge 13. A control device 14 for adjusting the free flow cross section of the water outlet 6 is formed by the component comprising the drive 32 and the toothed strip 16. Depending upon the adjusted elevation position of the toothed strip 16, more or less large intermediate spaces are formed between the teeth 33 and the threshold edge 13 whereby the volume flow of the water, which exits through the water outlet 6, can be adjusted. The control device 14 described above can be adjusted by the user as required. It is noted that it is possible to incorporate the control device 14 in a control loop for adapting and maintaining the exiting water volume flow constant.

The water film 4 can be adapted to the different weather conditions and inclination angles a of the carrier construction 21 in combination with a suitable higher-order, for example, computer-controlled open loop control or closed loop control. For optimal flow or obtaining warm water, the above-described parameters can be adapted to the instantaneous conditions and also to the temperature target for the storage water. If, for example, the weather is cool and the sky cloudy, that is, when the temperature of the solar module 1 is not more than 30° C., a flow for cooling is not needed. Furthermore, no warm water can be obtained. The pump 27 (FIG. 1) can be switched off. However, if one wants to store warm water with as high a temperature as possible in the presence of intense sunshine, then one permits a water volume flow as low as possible to flow over the solar modules 1 to form the water film 4. In this way, the temperature of the water and therefore the obtainable temperature in the water tank gets to be as high as possible.

Between the two above-described extremes, virtually any desired intermediate values can be adjusted which define a good compromise between cooling action at the solar modules 1 and the targeted water temperature. The adjusted inclination angle α of the carrier construction 21 (FIG. 1) is an influencing parameter which plays a part and as a consequence of which a more or less high flow velocity of the water film 4 results. For a given pump capacity of the pump 27, the film thickness of the water film 4 reduces with an increasing inclination angle α and therewith increasing flow velocity. Insofar as a specific film thickness of the water film 4 is wanted, the inclination angle α (FIG. 1) therefore also has to be considered. For this reason, it is advantageous when, simultaneously, the incoming radiation from the sun's rays, the air temperature and water temperature as well as the roof inclination can be measured. Dependent upon these measured values and the desired targets of the cooling action and the obtainment of warm water, an automatic control of the pump power and therefore of the fill level in the second quieting chamber 8 can be carried out including the adjustment of the control device 14 with the toothed strip 16. For this purpose, it is advantageous to utilize a programmable logic controller (PLC) which can be equipped with different programs in accordance with the different requirements so that the user can easily activate the desired program in each case.

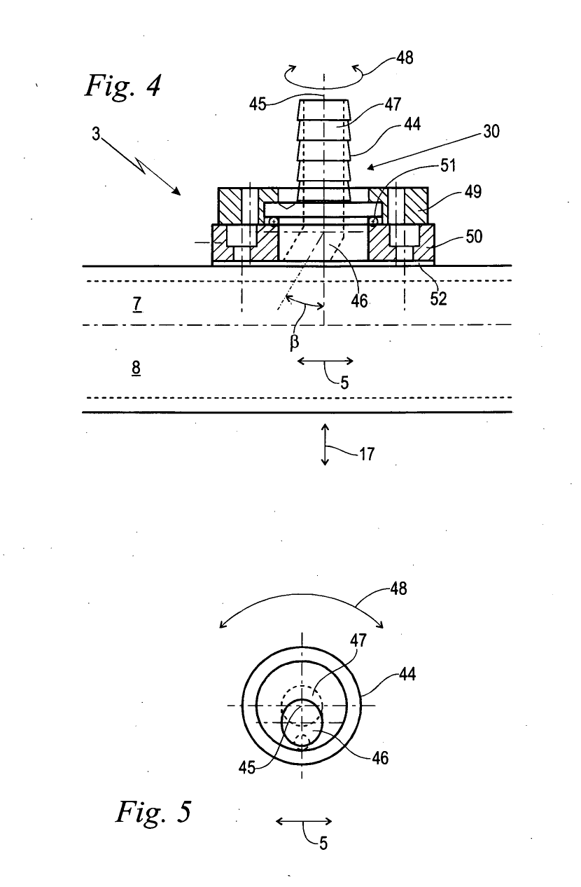

FIG. 4 is a plan view, in section, showing the flow arrangement 3 of FIGS. 1 to 3 in the region of the water feed 30. The section plane shown here lies in the plane defined by the horizontal transverse direction 5 and the inclination direction 17. The flow arrangement 3 is, referred to the transverse direction 5, configured to be mirror symmetrical. The water feed 30 opens centrally and transversely to the transverse direction 5 into the first quieting chamber 7. A water channel 47 of the water feed 30 lies with its longitudinal axis perpendicularly to the transverse direction 5. An inclined angle or off center arrangement can, however, also be practical.

In detail, the water feed 30 comprises a feed stub 44 which is held on a feed flange 50 by means of a clamping plate 49. The feed flange 50 is screwed to an end wall of the first quieting chamber 7 with a seal 52 interposed therebetween. The feed stub 44 has a peripherally-extending flange which is pressed seal tight against the feed flange 50 by means of the clamping plate 49 with a sealing ring 51 interposed therebetween. In this way, the feed stub 44 is held water tight with respect to the first quieting chamber 7. After loosening clamping screws (not shown) of the clamping plate 49, the feed stub 44 can be rotated about a rotational axis 45 in correspondence with arrow 48. The rotational axis 45 corresponds to the longitudinal axis of the feed stub 44. The adjusted rotational angular position is fixed by tightening the above-mentioned clamping screws.

The water channel 47, which passes through the feed stub 44, includes a water channel section 46 at the end of the stub 44 facing toward the first quieting chamber 7. This water channel section 46 lies at an angle β to the rotational axis 45. The angle β is greater than 0° and lies preferably in a range of 15°≦β≦45°. In the embodiment shown, the angle β is approximately 30°.

With the alignment of the water channel section 46 at the angle β relative to the rotational axis 45, adjustable deflecting means are formed for deflecting the incoming water flow into the horizontal transverse direction 5. Details in this context can be seen from viewing FIGS. 4 and 5 together.

FIG. 5 shows the feed stub 44 in cross section from the end of its exiting water channel section 46. As a consequence of its angle β (FIG. 4), the outlet cross section of the water channel section 46 lies with a radial offset to the center water channel 47, that is, the rotational axis 45. As shown in FIG. 5, a rotational angular position of the feed stub 44 is set and corresponds to a neutral position. In this neutral position, the water channel section 46 is centrally inclined downwardly but can also be centrally inclined upwardly. In both cases, the water channel section lies centered in the transverse direction so that, notwithstanding the angular position of the water channel section 46, no deflection of the water flow, which enters into the first quieting chamber 7 (FIG. 4), takes place in the transverse direction.

However, insofar as the solar modules 1 and/or the flow arrangement 3 (FIGS. 1, 2) exhibit an inclination error in the transverse direction 5, the feed stub 44 can be rotated to compensate for this inclination error in correspondence to the double arrow 48 starting from the neutral position shown in FIG. 5. In FIG. 4, a rotational angle is selected relative to the neutral position of FIG. 5 of, for example, 90° so that a maximum lateral deflection of the entering water flow occurs toward the left. This causes a water film, which is adjusted to be too thin on the left side, to become thickened. In the same manner, the feed stub 44 can, however, also be rotated in the opposite direction, that is, to the right. Here, the water film 4 (FIGS. 1 and 2) becomes thicker on the right side while the water film reduces in its thickness on the left side. Between these extremes in correspondence to the schematic of FIG. 4 and the neutral position of FIG. 5, any desired intermediate values of the rotational angle position of the feed stub 44 can be adjusted wherewith a desired thickness distribution of the water film 4 is adjustable in the transverse direction 5. Lateral inclination errors of the arrangement or also other errors, which influence the thickness distribution of the water film 4 (FIG. 1), can be accordingly compensated in a simple manner by rotational angle adjustment of the feed stub 44. Starting from the neutral position of FIG. 5, the feed stub 44 is rotated so far in correspondence to the double arrow 48 until a water film 4, which is uniformly thick in the transverse direction 5, adjusts over the assigned solar modules 1 (FIG. 1, 2) without a geometric compensation of the inclination error being required. The found rotational angle position can be easily fixed in a simple manner by means of the plate 49. Settling or the like which occurs later can be easily corrected after loosening the clamping plate 49 and by resetting the feed stub 44 in rotation.

In a plan view, FIG. 6 shows an enlarged detail schematic of the solar system of FIG. 1 in the region of two mutually adjoining solar modules 1 in the inclination direction 17. These solar modules 1 have a commercially conventional base surface. Accordingly, to cover the entire inhabited area, several such solar modules 1 are to be arranged one next to the other in the transverse direction and one beneath the other in the inclination direction 17. A joint 38 forms between the individual solar modules 1 in each case which here extends in the transverse direction 5. For covering a joint 38 and for guiding the water film 4 (FIG. 5) over this joint 38, a transition strip 36 is provided which extends in the transverse direction 5 and which completely covers or spans the joint 38 and has guide devices 37 which are distributed in the transverse direction 5 and aligned in the inclination direction 17. The guide devices 37 can be guide plates or the like running in the inclination direction 17. In the embodiment shown, the guide plates are formed by an arrangement of ribs 39 and channels 40 alternating in the transverse direction 5.

FIG. 7 shows a cross section view of the arrangement of FIG. 4 wherein the transition strip has a cross section which is approximately the shape of a half circle. Viewing FIGS. 4 and 7 together, it can be seen that the above-mentioned cross section of the transition strip 36 in combination with the ribs 39 and channels 40 is formed in that a corrugated rod is used which is halved in cross section along its length. For this purpose, a rod, which is circular in cross section and especially of plastic, is provided with a corrugated shape on a lathe. The wave runs in the peripheral direction. This corrugated rod is then cut open along its length. It is not necessary that it have an exactly halved cross section. Other peripheral sections of such a corrugated rod can be practical which, for example, constitute only one third of the cross section or of the periphery of one such corrugated rod. The ribs 39 and the channels 40 accordingly exhibit corrugated shapes in the transverse direction 5 and run, in the inclination direction, over the periphery of the transition strip 36 with this shape corresponding to a circular section. Alternatively, the transition strip 36 can also be formed with a commercial conventional corrugated tube partitioned in cross section along the length.

FIG. 7 shows that a seal 41 is arranged in the joint 38 between two mutually adjacent solar modules 1. This seal projects slightly above the surface of the solar modules 1 on the irradiation side 2. In this way and in addition to the mutual sealing of the two solar modules 1, the seal also serves as an attachment means for the transition strip 36 in that it engages in a lower slot of the transition strip 36. Furthermore, it is noted that the profile of the transition strip 36 is raised above the surface of the solar modules 1 on their irradiation side 2 in the assembled state and completely spans the joint 38 between the solar modules 1. In this way, the water film 4 of the upper solar module 1, referred to the inclination direction 17, is backed up at the transition strip 36 while forming a third water level 42 and then passes between the ribs 39 through the channels 40 (FIG. 6) in correspondence to arrow 43 while overcoming the joint 38 in the inclination direction 17 to the next-following lower solar module 1. As a consequence of the structuring of the transition strip 36, a uniform water film 4 then forms on the irradiation side 2 of the lower solar module in the same manner as with the upper solar module 1. The channels 40 are self-cleaning as a consequence of their type of construction, which is open outwardly or in radial direction, so that contamination or blockage because of leaves, et cetera, is avoided. As a supplement, a protective lattice can be mounted upstream of the transition strip 36 or a cage-like covering of the transition strip 36 to prevent blockage.

All joints 38, which run in the transverse direction 5, are, in this manner, provided with a transition strip 36 in correspondence to the schematic of FIG. 1 so that, on the irradiation side 2 of all solar modules 1, that is, on the total surface of the solar system, a uniform water film 4 forms.

It is understood that the foregoing description is that of the preferred embodiments of the invention and that various changes and modifications may be made thereto without departing from the spirit and scope of the invention as defined in the appended claims.

What is claimed is:

1. A flow arrangement for a solar system having an array of photovoltaic solar modules aligned inclined to the horizontal;
each one of said solar modules having an irradiation side facing toward the sun; said flow arrangement being provided to generate a water film flowing exposed to the ambient and forming on the irradiation side of each of said solar modules, said flow arrangement comprising:
a water source for supplying a flow of water;
a first quieting chamber connected to said water source for receiving said flow of water therefrom;
a second quieting chamber disposed downstream of said first quieting chamber in a throughflow direction;
a partition wall running between said first and second quieting chambers and defining a flow-over edge extending in a horizontal transverse direction over which water flows from said first quieting chamber to said second quieting chamber in said throughflow direction; and,
said second quieting chamber having a water outlet extending in said horizontal transverse direction from which water flows to form said water film.

2. The flow arrangement of claim 1, wherein said flow-over edge is an upper overflow edge over which water falls in a weight force direction.

3. The flow arrangement of claim 2, wherein said first and second quieting chambers extend over the entire width of said water outlet.

4. The flow arrangement of claim 3, wherein said first quieting chamber has a quieting lattice mounted therein.

5. The flow arrangement of claim 4, wherein said water outlet is defined by a threshold having a threshold edge extending in said horizontal transverse direction.

6. The flow arrangement of claim 5, further comprising a control unit for adjusting the free flow cross section of said water outlet.

7. The flow arrangement of claim 6, wherein said control unit is defined by a toothed strip adjustable in elevation and overlapping said threshold edge.

8. The flow arrangement of claim 7, wherein said water source comprises a water feed opening into said first quieting chamber;
said water feed being transverse to said horizontal transverse direction; and, adjustable deflecting means arranged in the region of said water feed for deflecting an entering flow of water in said horizontal transverse direction.

9. The flow arrangement of claim 8, wherein said water feed is centered with respect to said first quieting chamber.

10. The flow arrangement of claim 8, wherein said water feed comprises a rotatable feed stub defining a rotational axis lying transversely to said horizontal transverse direction; said feed stub including a water channel segment facing toward said first quieting chamber; and, said water channel segment lying at an angle (β) to said rotational axis to define said deflecting means.

11. A solar system comprising:
an array of photovoltaic solar modules aligned inclined to the horizontal;
each one of said solar modules having an irradiation side facing toward the sun;
a flow arrangement for generating a water film flowing exposed to the ambient and forming on the irradiation side of each of said solar modules; and,
said flow arrangement including:
a water source for supplying a flow of water;
a first quieting chamber connected to said water source for receiving said flow of water therefrom;
a second quieting chamber disposed downstream of said first quieting chamber in a throughflow direction;
a partition wall running between said first and second quieting chambers and defining a flow-over edge extending in a horizontal transverse direction over which water flows from said first quieting chamber to said second quieting chamber in said throughflow direction; and,
said second quieting chamber having a water outlet extending in said horizontal transverse direction from which water flows to form said water film.

12. The solar system of claim 11, wherein each one of said modules has a predetermined width and said water outlet has a width corresponding to the width of an individual one of said solar modules.

13. The solar system of claim 12, wherein said water is admixed with surfactants to form said water film.

14. The solar system of claim 11, wherein each one of said solar modules defines a surface on said irradiation side thereof; said surface has longitudinal guides for said water film; and, said longitudinal guides run in an inclined direction.

15. The solar system of claim 11, further comprising a control arrangement for effecting a fill level control of the water in at least one of said first and second quieting chambers.

16. The solar system of claim 11, wherein each two mutually adjoining ones of said solar modules in a direction of inclination conjointly define a transition region therebetween; said solar system further comprises a transition strip for assembly in said transition region and said transition strip extends in said horizontal transverse direction; and, said transition strip having guide devices distributed in said horizontal transverse direction and aligned in said direction of inclination.

17. The solar system of claim 16, wherein said each two mutually adjoining ones of said solar modules in said direction of inclination conjointly define a joint at said transition region therebetween; each one of said solar modules defines a surface on said irradiation side thereof; said transition strip is defined by a profile spanning said joint and projecting above the respective surfaces of said modules when in the assembled state; and, said guide devices comprising a plurality of ribs and a plurality of channels alternating with one another.

18. The solar system of claim 17, wherein said transition strip is defined by a corrugated rod cut along its length.
